(19) United States
(12) Patent Application Publication
(10) Pub. No.: US 2015/0187958 A1
(43) Pub. Date: Jul. 2, 2015

(54) IGZO Devices with Reduced Electrode Contact Resistivity and Methods for Forming the Same

(71) Applicant: Intermolecular Inc., San Jose, CA (US)

(72) Inventor: Khaled Ahmed, Anaheim, CA (US)

(73) Assignee: Intermolecular Inc., San Jose, CA (US)

(21) Appl. No.: 14/140,768

(22) Filed: Dec. 26, 2013

(51) Int. Cl. H01L 29/786; H01L 21/443; H01L 29/66

(52) U.S. Cl. CPC H01L 29/78618; H01L 29/66969; H01L 29/7869; H01L 29/78696; H01L 21/443

(57) ABSTRACT

Embodiments described herein provide indium-gallium-zinc oxide (IGZO) devices, such as IGZO thin-film transistors (TFTs), and methods for forming such devices. A substrate is provided. A gate electrode is formed above the substrate. An IGZO channel layer is formed above the gate electrode. A contact layer is formed above the IGZO channel layer. The contact layer includes arsenic. A source electrode and a drain electrode are formed above the contact layer.

### TECHNICAL FIELD

The present invention relates to indium-gallium-zinc oxide (IGZO) devices. More particularly, this invention relates to methods for forming IGZO devices, such as thin-film transistors (TFTs), with reduced electrode contact resistivity and methods for forming such devices.

### BACKGROUND OF THE INVENTION

Indium-gallium-zinc oxide (IGZO) devices, such as IGZO thin-film transistors (TFTs) have attracted a considerable amount of attention due to the associated low cost, room temperature manufacturing processes with good uniformity control, high mobility for high speed operation, and the compatibility with transparent, flexible, and light display applications. Due to these attributes, IGZO TFTs may even be favored over low cost amorphous silicon TFTs and relatively high mobility polycrystalline silicon TFT for display device applications. IGZO devices typically utilize amorphous IGZO (a-IGZO).

Recent developments in the field suggest that the use of crystalline IGZO may provide improved electrical and chemical stability. However, the use of crystalline IGZO may inhibit the performance of the device to relatively high contact resistivity with the source and drain electrodes.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a cross-sectional view of a substrate with gate electrode formed above.

FIG. 2 is a cross-sectional view of the substrate of FIG. 1 with a gate dielectric layer formed above the gate electrode and the substrate.

FIG. 3 is a cross-sectional view of the substrate of FIG. 2 with an indium-gallium-zinc oxide (IGZO) layer formed above the gate dielectric layer.

FIG. 4 is a cross-sectional view of the substrate of FIG. 3 with an IGZO channel layer formed above the gate dielectric layer.

FIG. 5 is a cross-sectional view of the substrate of FIG. 4 with a contact layer formed above the IGZO channel layer.

FIG. 6 is a cross-sectional view of the substrate of FIG. 5 with source and drain electrodes formed above the contact layer.

FIG. 7 is a cross-sectional view of the substrate of FIG. 6 with a passivation layer formed above the source and drain electrodes.

FIG. 8 is a cross-sectional view of an IGZO device according to some embodiments.

FIG. 9 is a simplified cross-sectional diagram of a physical vapor deposition (PVD) tool according to some embodiments.

FIG. 10 is a simplified cross-sectional diagram of plasma processing tool according to some embodiments.

FIG. 11 is a flow chart illustrating a method for forming IGZO devices according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

Some embodiments described herein provide indium-gallium-zinc oxide (IGZO) devices, such as IGZO thin-film transistors (TFTs), with improved (i.e., reduced) electrode contact resistivity, while still maintaining the high channel mobility normally associated with the use of IGZO channels, particularly those using crystalline IGZO (c-IGZO). In some embodiments, the electrode contact resistivity is reduced by forming an arsenic-containing layer (i.e., a contact layer) between the IGZO channel and the source and drain electrodes.

In some embodiments, the contact layer is formed by depositing an arsenic-containing material above the IGZO channel. The arsenic-containing material may include (i.e., in addition to arsenic) titanium, molybdenum, or a combination thereof. In some embodiments, the arsenic-containing material is a titanium-arsenic alloy or a titanium-molybdenum-arsenic alloy. In some embodiments, the contact layer includes a first sub-layer made of arsenic and a second sub-layer made of titanium, molybdenum, or a combination thereof.

In some embodiments, the contact layer includes arsenic-doped IGZO (e.g., a layer of arsenic-doped IGZO). The arsenic-doped IGZO may be formed by implanting arsenic ions into the upper surface (or upper portion) of the IGZO channel. The ion implantation may be performed using a plasma doping process utilizing an arsenic doping source.

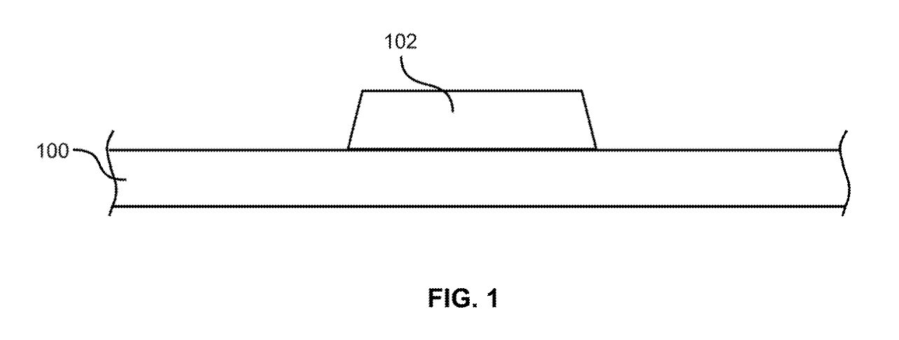

FIGS. 1-7 illustrate a method for forming an IGZO TFT (or more generically, an IGZO device), according to some embodiments. Referring now to FIG. 1, a substrate 100 is shown. In some embodiments, the substrate 100 is transparent and is made of, for example, glass. The substrate 100 may have a thickness of, for example, between about 0.01 centimeters (cm) and about 0.5 cm. Although only a portion of the substrate 100 is shown, it should be understood that the substrate 100 may have a width of, for example, between about 5.0 cm and about 4.0 meters (m). Although not shown, in some embodiments, the substrate 102 may have a dielectric layer (e.g., silicon oxide) formed above an upper surface thereof. In such embodiments, the components described below are formed above the dielectric layer. Also, in some embodiments, the substrate 100 is at least partially made of a of a semiconductor material (e.g., silicon, germanium, gallium arsenide, etc.). For example, in some embodiments, the substrate includes glass with a layer of semiconductor material formed thereon.

Still referring to FIG. 1, a gate electrode 102 is formed above the substrate 100. In some embodiments, the gate electrode 102 is made of a conductive material, such as copper, silver, aluminum, manganese, molybdenum, or a combination thereof. The gate electrode may have a thickness of, for example, between about 20 nanometers (nm) and about 500 nm. Although not shown, it should be understood that in some embodiments, a seed layer (e.g., a copper alloy) is formed between the substrate 100 and the gate electrode 102.

It should be understood that the various components above the substrate, such as the gate electrode 102 and those described below, are formed using processing techniques suitable for the particular materials being deposited, such as PVD (e.g., co-sputtering in some embodiments), chemical vapor deposition (CVD), plasma-enhanced CVD (PECVD), electroplating, etc. Furthermore, although not specifically shown in the figures, it should be understood that the various components formed above the substrate 100, such as the gate electrode 102, may be sized and shaped using a photolithography process and an etching process, as is commonly understood, such that the components are formed above selected regions of the substrate 100.

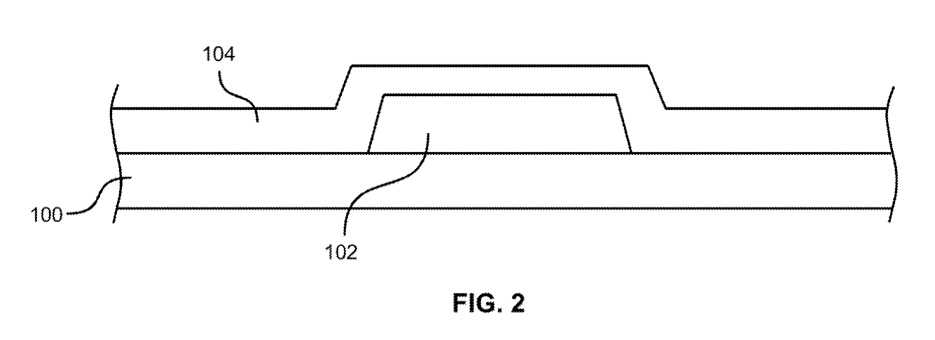

Referring to FIG. 2, a gate dielectric layer 104 is then formed above the gate electrode 102 and the exposed portions of the substrate 100. The gate dielectric layer 104 may be made of, for example, silicon oxide, silicon nitride, or a high-k dielectric (e.g., having a dielectric constant greater than 3.9), such as zirconium oxide, hafnium oxide, or aluminum oxide. In some embodiments, the gate dielectric layer 104 has a thickness of, for example, between about 10 nm and about 500 nm.

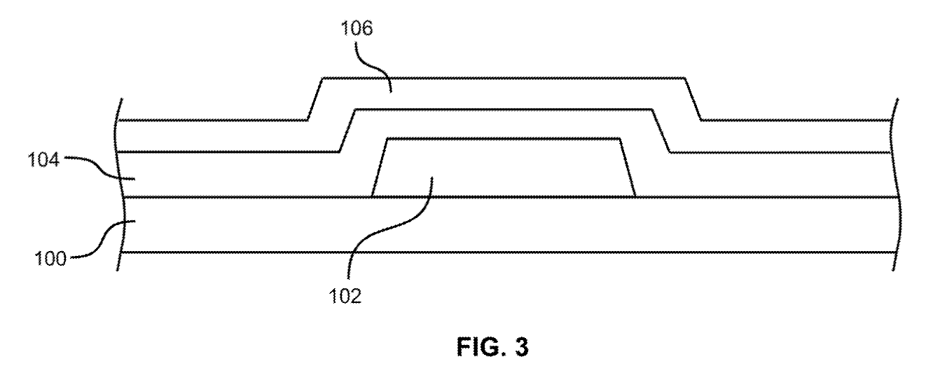

As shown in FIG. 3, an IGZO layer 106 is then formed above the gate dielectric layer 104. The IGZO layer 106 may be made of IGZO in which a ratio of the respective elements is, for example, 1:1:1:1-3. In some embodiments, the IGZO within the IGZO layer 106 is deposited as amorphous IGZO (a-IGZO). However, in some embodiments, the IGZO is formed or deposited using processing conditions to enhance the crystalline structure thereof. In some embodiments, the IGZO layer 106 is formed using PVD. The IGZO may be deposited from a single target that includes indium, gallium, and zinc (e.g., an indium-gallium-zinc alloy target or an IGZO target), but two or more targets may also used (e.g., co-sputtering with an indium-zinc target and a gallium target). The IGZO layer 106 may have a thickness of, for example, between about 10 nm and about 100 nm.

Although not specifically shown, in some embodiments, the IGZO layer 106 (and the other components shown in FIG. 3) may then undergo an annealing process. In some embodiments, the annealing process includes a relatively low temperature (e.g., less than about 600° C., preferably less than about 450° C.) heating process in, for example, an ambient gaseous environment (e.g., nitrogen, oxygen, or ambient/air) to (further) enhance the crystalline structure of the IGZO. The heating process may occur for between about 1 minute and about 200 minutes. After the annealing (or heating) process, the IGZO layer 106 may (substantially) include crystalline IGZO (c-IGZO). As used herein a “crystalline” material (e.g., c-IGZO) may be considered to be one that is more than 30% crystalline by volume, as determined by a technique such as X-ray Diffraction (XRD). In some embodiments, the c-IGZO is c-axis aligned crystal (CAAC) IGZO, as is commonly understood.

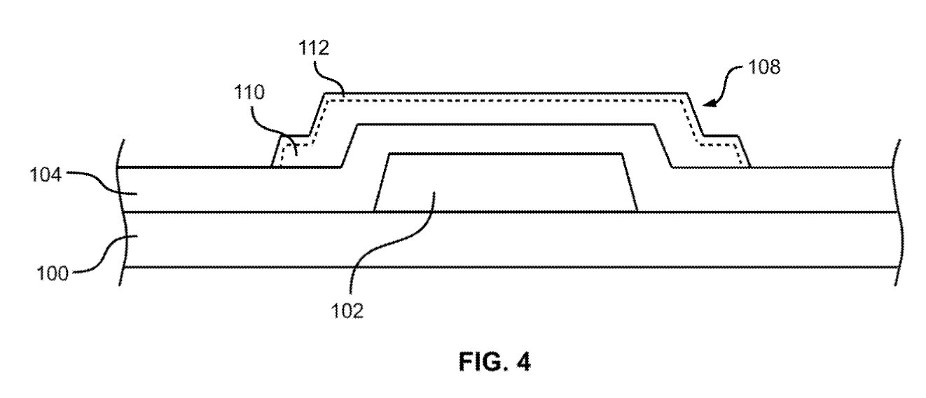

Referring to FIG. 4, after the annealing process, the IGZO layer 106 is patterned (e.g., etched) to form an IGZO channel (or channel layer) 108 (e.g., made of substantially c-IGZO) above the gate dielectric layer 104, over the gate electrode 102. As shown in FIG. 4, in some embodiments, the IGZO channel layer 108 may be considered to include a lower portion (or first IGZO channel layer) 110 and an upper portion (or second IGZO channel layer) 112 (e.g., formed above the lower portion 110). The upper portion 112 of the IGZO channel layer 108 may have a thickness that is significantly less than that of the lower portion 110 (e.g., between about 3 nm and about 15 nm).

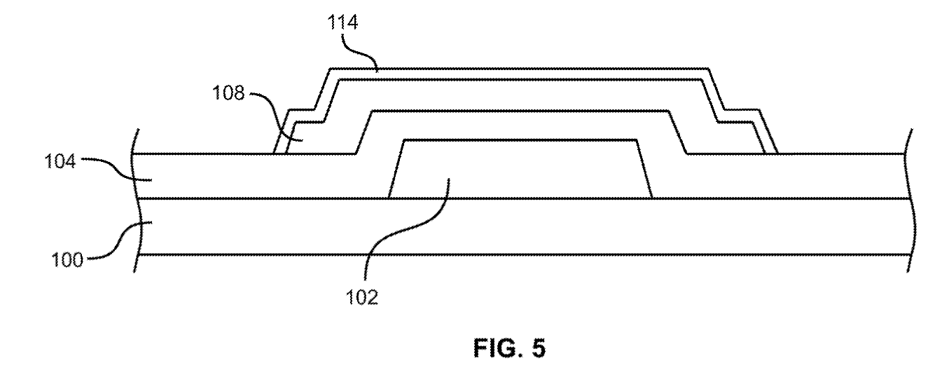

Next, as shown in FIG. 5, a contact layer 114 is formed above the IGZO channel layer 108 (or at least above the lower portion 110 of the IGZO channel layer 108 shown in FIG. 4). In some embodiments, the contact layer 114 includes arsenic.

In some embodiments, the contact layer 114 is formed by depositing an arsenic-containing material above the IGZO channel layer 108. The arsenic-containing material may include titanium, molybdenum, or a combination thereof (in addition to arsenic). In some embodiments, the contact layer 114 includes (or is made of) titanium-arsenic alloy and/or titanium-molybdenum-arsenic alloy. The contact layer 114 may include multiple sub-layers. For example, the contact layer 114 may include a metallic arsenic sub-layer and a sub-layer including titanium, molybdenum, or a combination thereof (e.g., titanium-molybdenum alloy). In some embodiments, the contact layer 114 is formed using, for example, PVD, and has a thickness of between about 3 nm and about 15 nm, such as about 5 nm. Although not shown, in some embodiments, some of the material of the contact layer (e.g., arsenic) may diffuse into the IGZO channel layer 108.

In some embodiments, the contact layer 114 is formed by implanting (i.e., doping) arsenic ions into the IGZO channel layer 108 (e.g., implanting arsenic ions into the upper portion 112 of the IGZO channel layer 108 shown in FIG. 4).

In some embodiments, the doping process used to implant the arsenic ions is a plasma doping process. The plasma doping process may be performed using a doping source, a source of doping energy, and a doping dose. In some embodiments, the process include exciting the doping source into a plasma status and implanting dopant ions in the excited plasma into a specimen (e.g., the substrate 100 and/or the IGZO channel layer 108). For example, when a bias voltage is applied to the specimen, the dopant ions in the plasma may simultaneously gather over the surface of the specimen.

The doping source may be a material, such as a dopant gas, containing a dopant to be applied to the doped region. In some embodiments, the doping source may include (or be made of) arsine (AsH₃).

The doping energy may refer to a bias voltage applied to the specimen (e.g., the substrate 100 and/or the IGZO channel layer 108). The doping energy may be 20 kilovolts (kV) or less. In some embodiments, to achieve a shallow depth of the doped area, the doping energy is adjusted to be as small as possible. For example, the doping energy may be lower than approximately 1 kV (note that doping energies lower than approximately 20 kV are generally considered to be relatively low).

The doping dose affects the amount of implantation of the dopant. The doping dose ranges from about 1×10¹⁵ atoms/cm² to about 1×10¹⁷ atoms/cm². When the plasma doping process is performed using the doping dose of the above-described range, the dopant applied to the doped region forms a doping concentration of 1×10²⁰ atoms/cm³ or more. To facilitate the plasma doping process, a gas for exciting the plasma, such as argon, helium etc., may be introduced, as is commonly understood.

Because the plasma doping process uses a relatively low doping energy, most of the dopant remains on the surface (e.g., of the IGZO channel layer 108, or within the upper portion 112 of the IGZO channel layer 108 shown in FIG. 4). Therefore, the doping depth of the doped region formed by the plasma doping process may be controlled to be relatively shallow. In some embodiments, the doping depth is between about 3 nm and about 15 nm, such as about 10 nm, which may refer to the thickness of the contact layer 114 when formed using the doping process described above (i.e., the thickness of the upper portion 112 of the IGZO channel layer 108 shown in FIG. 4). Since the doping depth of the doped region is controlled to be shallow, the superior transport properties of the IGZO channel layer 108 are maintained.

It should be understood that when such a doping process is used to form the contact layer 114, the IGZO channel layer 108 may be considered to include only the lower portion 110 of the IGZO channel layer 108 shown in FIG. 4, while the upper portion 112 of the IGZO channel layer 108 is essentially converted into the contact layer 114 (i.e., via the doping process).

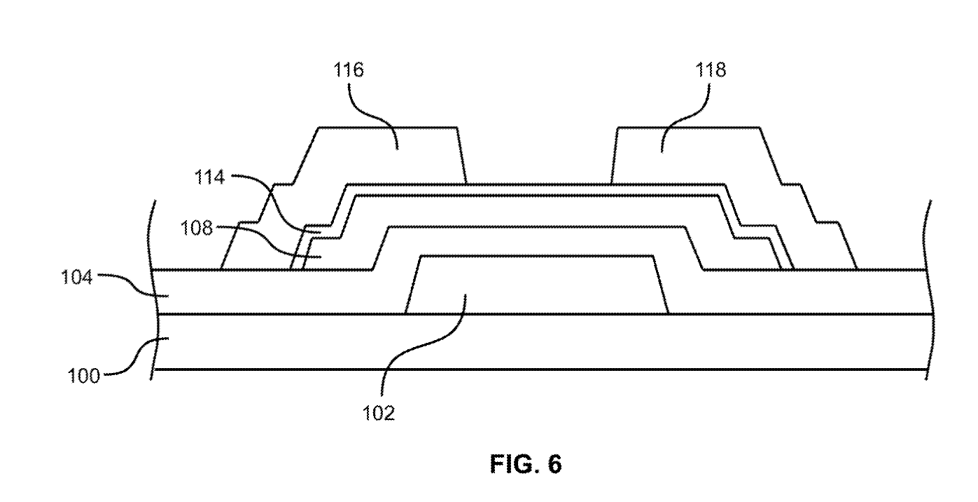

Referring now to FIG. 6, a source electrode (or region) 116 and a drain electrode (or region) 118 are then formed above the contact layer 114. As shown, the source electrode 116 and the drain electrode 118 lie on opposing sides of, and partially overlap the ends of, the contact layer 114 and the IGZO channel 108. As will be appreciated by one skilled in the art, the source electrode 116 and the drain electrode 118 may be defined as shown in FIG. 6 using a “back-channel etch” (BCE) process to, for example, form the gap between the source electrode 116 and the drain electrode 118, which is vertically aligned with the gate electrode 102. However, in some embodiments, an etch-stop layer, as is commonly understood, may be formed above the contact layer 114 to facilitate the defining of the source electrode 116 and the drain electrode 118 (e.g., by protecting the IGZO during the etch process).

In some embodiments, the source electrode 116 and the drain electrode 118 are made of titanium, aluminum, molybdenum, copper, copper-manganese alloy, or a combination thereof. In some embodiments, the source electrode 116 and the drain electrode 118 include multiple sub-layers (e.g., sub-layers of titanium and titanium nitride). The source electrode 116 and the drain electrode 118 may have a thickness of, for example, between about 20 nm and 500 nm.

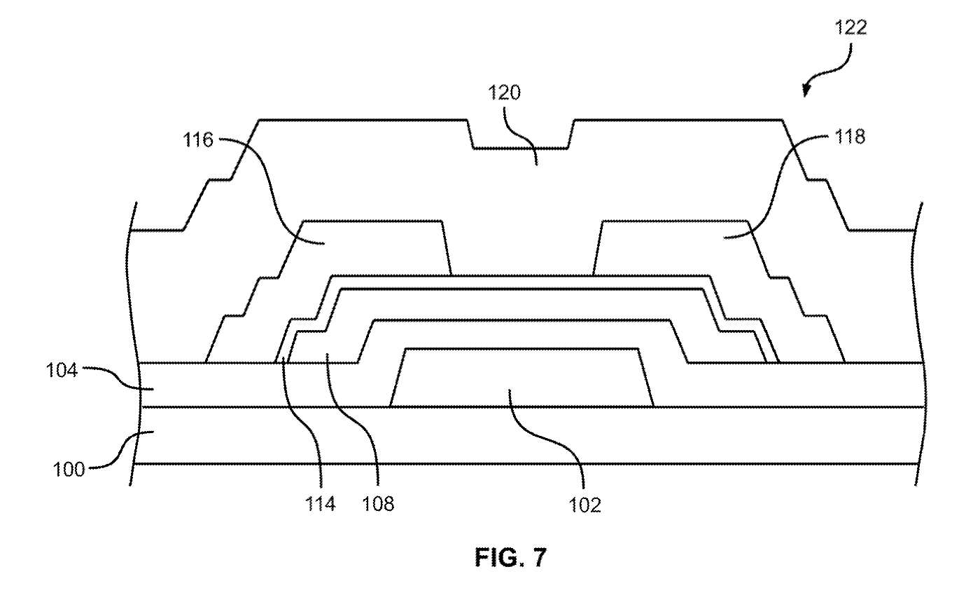

Referring to FIG. 7, a passivation layer 120 is then formed above the source electrode 116, the drain electrode 118, and the exposed portions of the gate dielectric layer 104 and the contact layer 114. In some embodiments, the passivation layer 120 is made of silicon oxide, silicon nitride, aluminum oxide, aluminum nitride, or a combination thereof and has a thickness of, for example, between about 0.1 μm and about 1.5 μm.

The deposition of the passivation layer 120 may substantially complete the formation of an IGZO device 122, such as an inverted, staggered bottom-gate IGZO TFT. It should be understood that although only a single device 122 is shown as being formed on a particular portion of the substrate 100 in FIGS. 1-7, the manufacturing processes described above may be simultaneously performed on multiple portions of the substrate 100 such that multiple devices 122 are simultaneously formed, as is commonly understood. Further, although not shown, in some embodiments, such as those intended for use in display applications, pixel electrodes may also be formed above the substrate 100 during the formation of the IGZO device(s) 122. The pixel electrodes may be made of a transparent conductive material, such as indium-tin oxide (ITO).

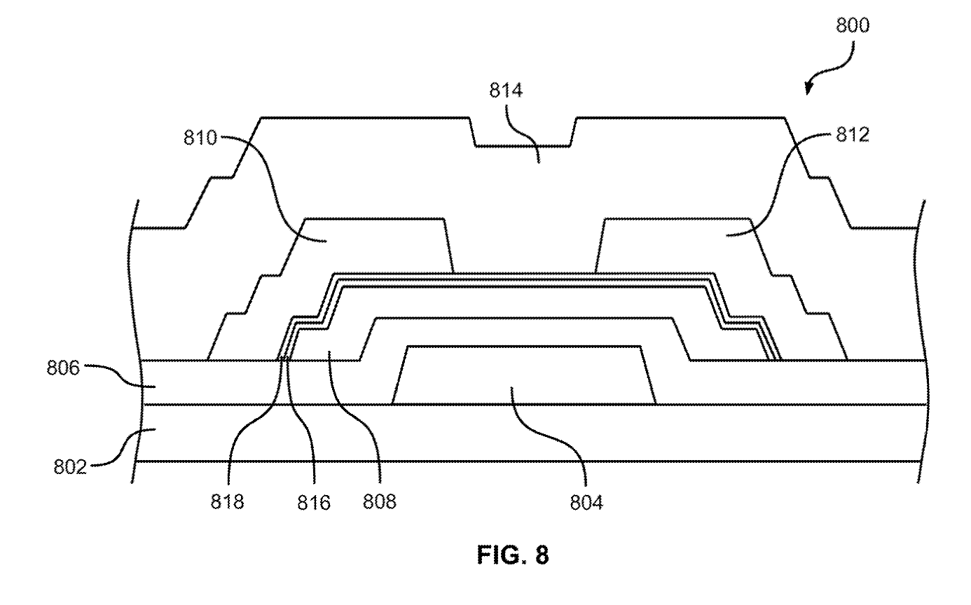

FIG. 8 illustrates an IGZO device (e.g., an IGZO TFT) 800 according to some embodiments. The IGZO device 800 may be similar to the IGZO device 122 shown in FIG. 7 and likewise include a substrate 802, a gate electrode 804, a gate dielectric layer 806, an IGZO channel layer 808, a source electrode 810, a drain electrode 812, and a passivation layer 814, which are similar to those described above. Also like the previously-described embodiments, the IGZO device 800 includes a contact layer formed between the IGZO channel layer 808 and the source and drain electrodes 810 and 812.

Of particular interest in FIG. 8 is that the depicted embodiment includes a contact layer having multiple sub-layers as discussed above. In particular, the contact layer includes a first (or lower) sub-layer 816 and a second (or upper) sub-layer 818. In some embodiments, one of the sub-layers 816 and 818 includes metallic arsenic and the other includes titanium, molybdenum, or a combination thereof. For example, the first sub-layer 816 may be made of arsenic, and the second sub-layer 818 may be made of titanium-molybdenum alloy. The sub-layers 816 and 818 may be formed using, for example, PVD and each may have a thickness of, for example, between about 2 nm and about 7 nm.

The arsenic, either in the arsenic-containing material deposited above the IGZO or implanted within the IGZO, may essentially behave like an N-type dopant with respect to the IGZO. As a result, the contact layer(s) described above provides ultra-low specific contact resistivity at the source and drain electrodes. Also, the use of the c-IGZO within the channel provides the device(s) with high channel mobility and electrical and chemical stability, allowing excellent device performance, especially with respect to reliability and longevity. As a result, high performance IGZO devices (e.g., IGZO TFTs) are provided.

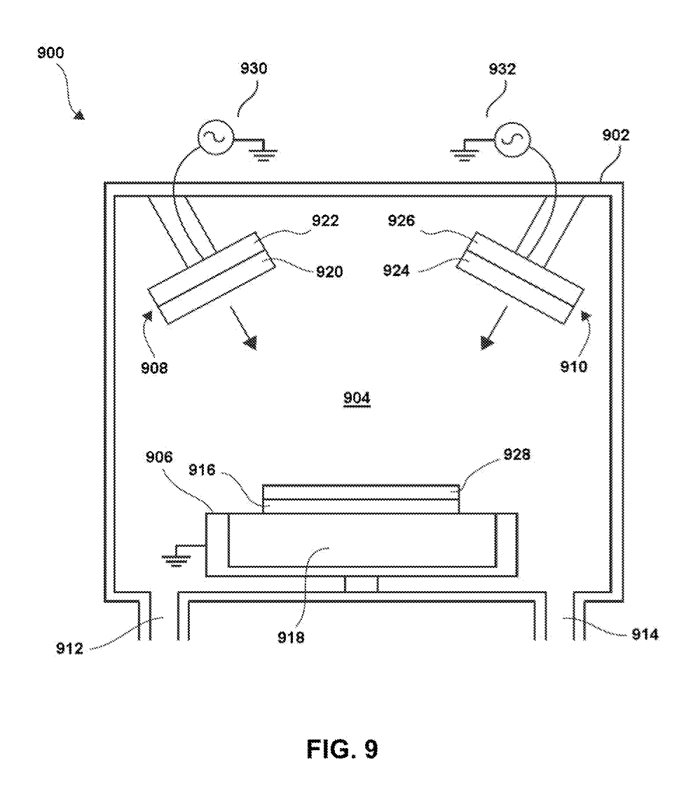

FIG. 9 provides a simplified illustration of a physical vapor deposition (PVD) tool (and/or system) 900 which may be used, in some embodiments, to form the IGZO channel layers and contact layers (and/or other components of the IGZO devices), described above. The PVD tool 900 shown in FIG. 9 includes a housing 902 that defines, or encloses, a processing chamber 904, a substrate support 906, a first target assembly 908, and a second target assembly 910.

The housing 902 includes a gas inlet 912 and a gas outlet 914 near a lower region thereof on opposing sides of the substrate support 906. The substrate support 906 is positioned near the lower region of the housing 902 and in configured to support a substrate 916. The substrate 916 may be a round substrate having a diameter of, for example, about 200 mm or about 300 mm. In other embodiments (such as in a manufacturing environment), the substrate 916 may have other shapes, such as square or rectangular, and may be significantly larger (e.g., about 0.5 m to about 4 m across). The substrate support 906 includes a support electrode 918 and is held at ground potential during processing, as indicated.

The first and second target assemblies (or process heads) 908 and 910 are suspended from an upper region of the housing 902 within the processing chamber 904. The first target assembly 908 includes a first target 920 and a first target electrode 922, and the second target assembly 910 includes a second target 924 and a second target electrode 926. As shown, the first target 920 and the second target 924 are oriented or directed towards the substrate 916. As is commonly understood, the first target 920 and the second target 924 include one or more materials that are to be used to deposit a layer of material 928 on the upper surface of the substrate 916.

The materials used in the targets 920 and 924 may, for example, include indium, gallium, zinc, tin, silicon, silver, aluminum, manganese, molybdenum, zirconium, hafnium, titanium, molybdenum, copper, or any combination thereof (i.e., a single target may be made of an alloy of several metals). Additionally, the materials used in the targets may include oxygen, nitrogen, or a combination of oxygen and nitrogen in order to form oxides, nitrides, and oxynitrides. Additionally, although only two targets 920 and 924 are shown, additional targets may be used.

The PVD tool 900 also includes a first power supply 930 coupled to the first target electrode 922 and a second power supply 932 coupled to the second target electrode 924. As is commonly understood, in some embodiments, the power supplies 930 and 932 pulse direct current (DC) power to the respective electrodes, causing material to be, at least in some embodiments, simultaneously sputtered (i.e., co-sputtered) from the first and second targets 920 and 924. In some embodiments, the power is alternating current (AC) to assist in directing the ejected material towards the substrate 916.

During sputtering, inert gases (or a plasma species), such as argon or krypton, may be introduced into the processing chamber 904 through the gas inlet 912, while a vacuum is applied to the gas outlet 914. The inert gas(es) may be used to impact the targets 920 and 924 and eject material therefrom, as is commonly understood. In embodiments in which reactive sputtering is used, reactive gases, such as oxygen and/or nitrogen, may also be introduced, which interact with particles ejected from the targets (i.e., to form oxides, nitrides, and/or oxynitrides).

Although not shown in FIG. 9, the PVD tool 900 may also include a control system having, for example, a processor and a memory, which is in operable communication with the other components shown in FIG. 9 and configured to control the operation thereof in order to perform the methods described herein.

Although the PVD tool 900 shown in FIG. 9 includes a stationary substrate support 906, it should be understood that in a manufacturing environment, the substrate 916 may be in motion (e.g., an in-line configuration) during the formation of various layers described herein.

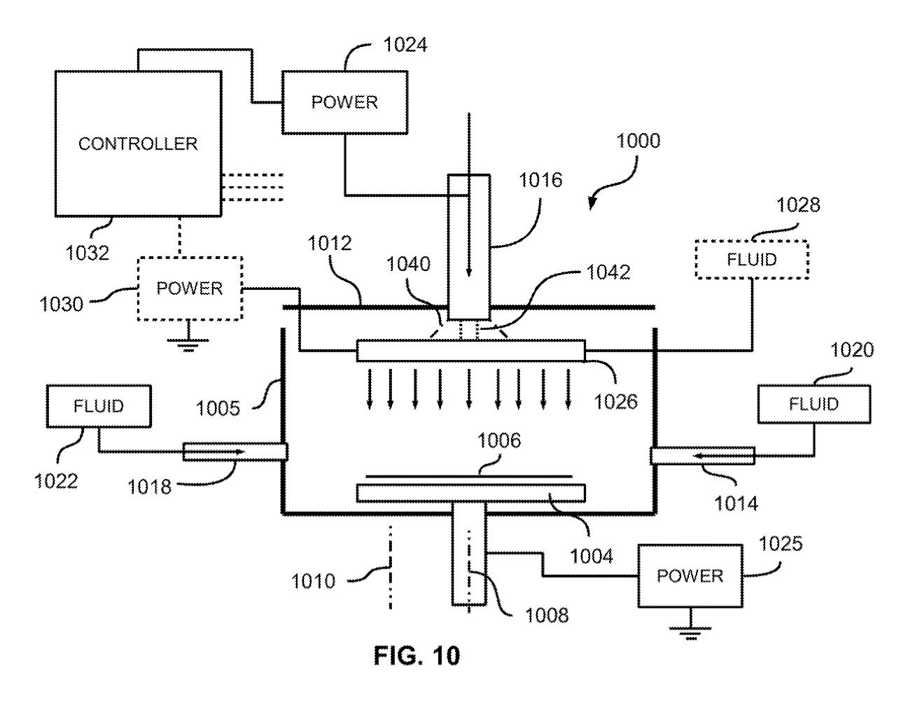

FIG. 10 illustrates a plasma processing tool (or chamber) 1000 according to some embodiments. The plasma processing tool 1000 may be used, in some embodiments, to form the contact layers (i.e., in embodiments in which the contact layer is formed via doping) described above.

The processing tool 1000 includes a housing with a sidewall 1005 and a lid 1012, which define a processing chamber, and a substrate support 1004 which is configured to hold a substrate 1006 disposed thereon. The substrate support 1004 may be any known substrate support, including but not limited to a vacuum chuck, electrostatic chuck or other known mechanisms. The substrate support 1004 is capable of both rotating around its own central axis 1008 (referred to as “rotation” axis, which is congruent with a central axis of the substrate 1006), and rotating around a second axis 1010 (referred to as “revolution” axis). Other substrate supports, such as an XY table, can also be used for site-isolated processing. In addition, the substrate support 1004 may move in a vertical direction (i.e., away from or towards lid 1012). It should be appreciated that the rotation and movement in the vertical direction may be achieved through known drive mechanisms which include magnetic drives, linear drives, worm screws, lead screws, a differentially pumped rotary feed through drive, etc. Power source 1024 provides power to plasma generation source 1016, while power source 1025 provides power to the substrate support 1004. It should be appreciated that power sources 1024 and 1025 may output a direct current (DC) power supply, a pulsed DC power supply, or a radio frequency (RF) power supply.

The substrate 1006 may be a conventional round 200 mm, 300 mm substrate, or any other larger or smaller substrate/wafer size. In some embodiments, the substrate 1006 may be a square, rectangular, or other shaped substrate. One skilled in the art will appreciate that the substrate 1006 may be a blanket substrate, a coupon (e.g., partial wafer), or even a patterned substrate having predefined regions.

Still referring to FIG. 10, the plasma generation source (or system) 1016 extends through the lid 1012. Fluid inlets 1014 and 1018 extend into the processing chamber through the sidewall 1005. Fluid inlet 1014 is in fluid communication with a fluid source 1020, while fluid inlet 1018 is in fluid communication with a fluid source 1022. In some embodiments, fluid inlets 1014 and 1018 may be in fluid communication with the same fluid source. It should be appreciated that fluid inlets 1014 and 1018 may extend around a surface of the substrate 1006. In some embodiments, fluid inlets 1014 and 1018 are configured as ring portions surrounding substrate 1006.

In some embodiments, fluid inlets 1014 and 1018 are movable to vertically translate along with the substrate support 1004 so that each fluid inlet remains proximate to an edge of substrate 1006. For example, the ring portions may be coupled to an appropriate drive such as a worm gear, linear drive, etc., so that the fluid inlets 1014 and 1018 track the movement of the substrate and substrate support. The plasma generation source 1016 is operable to provide a plasma activated species proximate to a surface of substrate 1006. The plasma activated species provided by plasma generation source 1016 has a non-reactive outer portion 1040 surrounding a reactive inner portion 1042 in accordance with some embodiments. It should be further appreciated that plasma generation source 1016 may be a commercially available inductively coupled radio frequency (RF) plasma generation source.

It should also be appreciated that a plasma activated species may refer to the reactive atomic and molecular radicals converted from the precursor gas through interaction with the plasma. Further, the plasma may consist of non-charged species (e.g., radicals) and charged species (e.g., ions and electrons). Additionally, the plasma generation source (or system) 1016 may include means for generating multiple types of plasma simultaneously.

In some embodiments, a plasma provided through the plasma generation source 1016 includes, for example, argon, helium, hydrogen, bromine, nitrogen, oxygen, ammonia, nitrogen trifluoride (or a combination thereof) based plasma referred to as a first precursor. The film feedstock provided by fluid inlets 1014 and 1018 (e.g., from the fluid supplies 1020 and 1022) may be any suitable feedstock for the desired deposition layer and may be referred to as a second precursor. In some embodiments, the feedstock includes arsenic (e.g., arsine gas).

Thus, for some embodiments described herein, the first precursor carries the plasma activated species and activates the second precursor (or the doping source) proximate to the substrate surface at a specific site or region.

Still referring to FIG. 10, the processing tool 1000 also includes a showerhead 1026 suspended between the plasma generation source 1016 and the substrate 1006. Although not shown, the showerhead 1026 may be vertically translatable (i.e., movable) within the processing chamber. An additional fluid source 1028 may be provided and coupled to (i.e., in fluid communication with) the showerhead 1026. Fluid source 1028 may provide, for example, an inert gas to the showerhead during processing. Additionally, in some embodiments, the showerhead 1026 is grounded as shown in FIG. 10. However, in other embodiments, a power supply (and controller) 1030 may also be provided to control and modulate the charge on the showerhead 1026.

The processing tool 1000 also includes a controller (or control sub-system) 1032 which is in operable communication with the other components of the processing tool 1000, such as fluid sources 1020 and 1022, power supplies 1024 and 1025, etc. (not all connections are shown for clarity). The controller 1032 includes, for example, a processor and memory, such as random access memory (RAM) and a hard disk drive. The controller 1032 is configured to control the operation of the processing tool 1000 to perform the methods and processes described herein (e.g., the plasma doping described above).

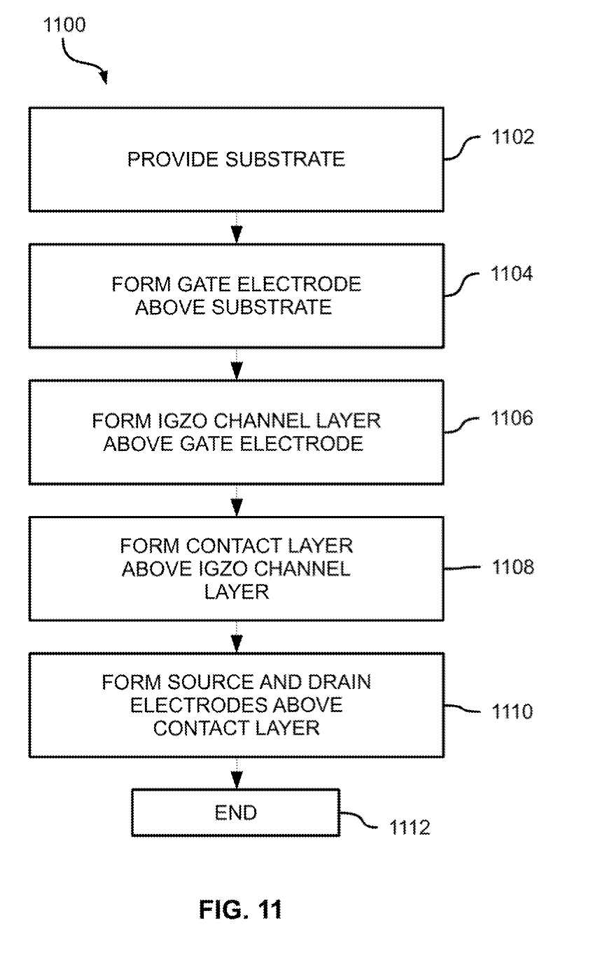

FIG. 11 illustrates a method 1100 for forming IGZO devices, such as IGZO TFTs, according to some embodiments. At block 1102, the method 1100 begins with a substrate being provided. As described above, in some embodiments, the substrate includes glass, a semiconductor material, or a combination thereof.

At block 1104, a gate electrode is formed above the substrate. The gate electrode may be made of a conductive material, such as copper, silver, aluminum, manganese, molybdenum, or a combination thereof.

At block 1106, an IGZO channel layer is formed above the gate electrode. The IGZO channel layer may be similar to the IGZO channel layer 108 shown in FIG. 4 as a whole. However, in some embodiments, the IGZO channel layer refers to only a portion of the IGZO channel 108 (i.e., the lower portion 110 of the IGZO channel layer 108).

At block 1108, a contact layer is formed above the IGZO channel layer. In some embodiments, the contact layer includes arsenic. The contact layer may include titanium, molybdenum, or a combination thereof (in addition to arsenic).

In some embodiments, the contact layer is formed by depositing an arsenic-containing material above the IGZO channel layer. The arsenic-containing material may include titanium-arsenic alloy and/or titanium-molybdenum-arsenic alloy. In some embodiments, the arsenic-containing material (or the contact layer) includes multiple sub-layers. The contact layer may be formed using, for example, PVD, and have a thickness of between about 3 nm and about 15 nm. In some embodiments, the contact layer is formed by implanting (i.e., doping) arsenic ions into the IGZO channel layer (e.g., implanting arsenic ions into the upper portion 112 of the IGZO channel layer 108 shown in FIG. 4).

At block 1110, source and drain electrodes are formed above the contact layer. The source and drain electrodes may made of, for example, titanium, aluminum, molybdenum, copper, copper-manganese alloy, or a combination thereof.

Although not shown, in some embodiments, the method 1100 includes the formation of additional components of an IGZO device, such as a gate dielectric layer and a passivation layer, as well as additional processing steps, such as an annealing process. At block 1112, the method 1100 ends.

Thus, in some embodiments, methods for forming an IGZO device are provided. A substrate is provided. A gate electrode is formed above the substrate. An IGZO channel layer is formed above the gate electrode. A contact layer is formed above the IGZO channel layer. The contact layer includes arsenic. A source electrode and a drain electrode are formed above the contact layer.

In some embodiments, methods for forming an IGZO TFT are provided. A substrate is provided. A gate electrode is formed above the substrate. A gate dielectric layer is formed above the gate electrode. An IGZO channel layer is formed above the gate electrode. A contact layer is formed above the IGZO channel layer. The contact layer includes arsenic. A source electrode and a drain electrode are formed above the contact layer. A passivation layer is formed above the source electrode and the drain electrode.

In some embodiments, IGZO devices are provided. Each IGZO device includes a substrate. A gate electrode is formed above the substrate. A gate dielectric layer is formed above the gate electrode. An IGZO channel layer is formed above the gate dielectric layer. A contact layer is formed above the IGZO channel layer. The contact layer includes arsenic. A source electrode and a drain electrode are formed above the contact layer.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method for forming an indium-gallium-zinc oxide (IGZO) device, the method comprising:
providing a substrate;
forming a gate electrode above the substrate;
forming a first IGZO channel layer above the gate electrode;
forming a contact layer above the first IGZO channel layer, wherein the contact layer comprises arsenic; and
forming a source electrode and a drain electrode above the contact layer.

2. The method of claim 1, wherein the forming of the contact layer comprises depositing an arsenic-containing material above the first IGZO channel layer.

3. The method of claim 2, wherein the arsenic-containing material comprises arsenic and one of titanium, molybdenum, or a combination thereof.

4. The method of claim 3, wherein the arsenic-containing material comprises titanium-molybdenum-arsenic alloy.

5. The method of claim 3, wherein the contact layer comprises a first sub-layer comprising arsenic and a second sub-layer comprising one of titanium, molybdenum, or a combination thereof.

6. The method of claim 3, wherein the arsenic-containing material is deposited above the first IGZO channel layer using physical vapor deposition (PVD).

7. The method of claim 1, wherein the forming of the contact layer comprises:
forming a second IGZO channel layer above the first IGZO channel layer, wherein the second IGZO channel layer has a thickness that is less than a thickness of the first IGZO channel layer; and
doping the second IGZO channel layer with arsenic.

8. The method of claim 7, wherein the doping of the second IGZO channel layer with arsenic comprises exposing the second IGZO channel layer to a plasma species.

9. The method of claim 1, further comprising forming a gate dielectric layer above the gate electrode, wherein the first IGZO channel layer is formed above the gate dielectric layer.

10. The method of claim 9, further comprising forming a passivation layer above the source electrode and the drain electrode.

11. A method for forming an indium-gallium-zinc oxide (IGZO) thin-film transistor (TFT), the method comprising:
providing a substrate;
forming a gate electrode above the substrate;
forming a gate dielectric layer above the gate electrode;
forming a first IGZO channel layer above the gate electrode;
forming a contact layer above the first IGZO channel layer, wherein the contact layer comprises arsenic;
forming a source electrode and a drain electrode above the contact layer; and
forming a passivation layer above the source electrode and the drain electrode.

12. The method of claim 11, wherein the forming of the contact layer comprises depositing an arsenic-containing material above the first IGZO channel layer, wherein the arsenic-containing material comprises arsenic and one of titanium, molybdenum, or a combination thereof.

13. The method of claim 12, wherein the arsenic-containing material comprises titanium-molybdenum-arsenic alloy.

14. The method of claim 12, wherein the contact layer comprises a first sub-layer comprising arsenic and a second sub-layer comprising one of titanium, molybdenum, or a combination thereof.

15. The method of claim 11, wherein the forming of the contact layer comprises:
forming a second IGZO channel layer above the first IGZO channel layer, wherein the second IGZO channel layer has a thickness that is less than a thickness of the first IGZO channel layer; and
doping the second IGZO channel layer with arsenic.

16. An indium-gallium-zinc oxide (IGZO) device comprising:
a substrate;
a gate electrode formed above the substrate;
a gate dielectric layer formed above the gate electrode;
an IGZO channel layer formed above the gate dielectric layer;
a contact layer formed above the IGZO channel layer, wherein the contact layer comprises arsenic; and
a source electrode and a drain electrode formed above the contact layer.

17. The IGZO device of claim 16, wherein the contact layer further comprises one of titanium, molybdenum, or a combination thereof.

18. The IGZO device of claim 17, wherein the contact layer comprises a first sub-layer comprising arsenic and a second sub-layer comprising one of titanium, molybdenum, or a combination thereof.

19. The IGZO device of claim 16, wherein the contact layer comprises arsenic-doped IGZO.

20. The IGZO device of claim 16, further comprising a passivation layer formed above the source electrode and the drain electrode.
